(19) United States
(12) Patent Application Publication
(10) Pub. No.: US 2015/0102990 A1
(43) Pub. Date: Apr. 16, 2015

(54) GATE DRIVING CIRCUIT, AND ARRAY SUBSTRATE AND DISPLAY PANEL THEREOF

(71) Applicant: SHENZHEN CHINA STAR OPTOELECTRONICS TECHNOLOGY CO. LTD., Shenzhen, Guangdong (CN)

(72) Inventor: Ping-Sheng Kuo, Shenzhen (CN)

(21) Appl. No.: 14/241,403

(22) PCT Filed: Jan. 23, 2014
(86) PCT No.: PCT/CN2014/071223

§ 371 Date: Jun. 4, 2014

(30) Foreign Application Priority Data
Oct. 12, 2013 (CN) 201310477103.2

(51) Int. Cl. G09G 3/36; H03K 17/56

(52) U.S. Cl. CPC G09G 3/3674; H03K 17/56; G09G 2320/043; G09G 2300/0478; G09G 2310/08
USPC 345/99; 327/109

(57) ABSTRACT

The present invention relates to a gate driving circuit, and an array substrate and a display panel thereof, wherein gate driving circuit includes multi-level gate driving units. A gate driving unit of each level comprises a starting unit, an energy storage unit, a pull-up unit, a first pull-down unit, a second pull-down unit and a third pull-down unit, wherein the second pull-down unit is coupled to the energy storage unit and a gate line, and configured to intermittently generate a second control signal based on a driving voltage, a clock pulse signal and a second reference voltage, and to pull the driving voltage and a gate signal on the gate line down to the second reference voltage. In addition, to prevent leakage current between the first reference voltage and the second reference voltage from causing burnout of a chip for reference voltage supply, a transistor between the first reference voltage and the second reference voltage, through which the leakage current possibly passes, is modified to be a plurality of transistors in series connection, such that the possibility of current leakage is reduced. Therefore, the gate driving circuit and the array substrate thereof provided in the present invention have improved reliability and longer service life, and can be applied to various display panels.

### FIELD OF THE INVENTION

The present disclosure relates to a liquid crystal display driving technology, and in particular, to a gate driving circuit, and an array substrate and a display panel thereof.

### BACKGROUND OF THE INVENTION

An existing liquid crystal display device includes a plurality of pixel units, and a gate driving circuit and a source driving circuit for driving the pixel units to operate, wherein the gate driving circuit includes multi-level gate driving units, and these gate driving units successively output gate signals through gate lines coupled to the gate driving units to control the turn-on of corresponding switch transistors in a display area, such that data signal output by the source driving circuit can be send into the corresponding pixel units to display images. Thus, the reliability of the gate driving circuit has a vital influence on accurate imaging.

As shown in FIG. 1, the gate driving units in the gate driving circuits currently adopted in the mainstream display panel manufacturers are substantially the same in structure, and may be divided, according to different functions thereof, into a plurality of function modules, including a starting unit 10, an energy storage unit 20, a pull-up unit 30, a first pull-down unit 40, a second pull-down unit 50, etc. The starting unit 10 is configured to transmit an enabling signal ST to the energy storage unit 20. The energy storage unit 20 configured to execute a charging procedure according to the enabling signal ST to output a driving voltage Q. The pull-up unit 30 is configured to pull up a gate signal G on the gate line according to the driving voltage Q and a clock pulse signal CLK. The first pull-down unit 40 is configured to pull down the driving voltage Q and the gate signal G when the gate signal G is of high level (i.e., during an action period of the gate driving unit). The second pull-down unit 50 is configured to pull down the driving voltage Q and the gate signal G when the gate signal G is of low level (i.e., during an inaction period of the gate driving unit). In the case, in order to prevent the driving voltage Q and the gate signal G from deviation due to constantly accumulated charges in the circuit during the inaction period of the gate driving unit, the second pull-down unit 50 needs to be constantly under a pull-down operating state, but this may cause reliability degradation after a long-term operation. As it should be, in some existing gate driving circuits, a third pull-down unit 60 is further arranged and operates in cooperation with the second pull-down unit 50 to pull down the driving voltage Q and the gate signal G in an alternate manner, in order to reduce the operating time of the second pull-down unit 50.

However, it is found by those researchers of the present disclosure through long-term researches and tests that, the condition of alternate operation of the second pull-down unit 50 and the third pull-down unit 60 is not quite satisfactory in practice. After a liquid crystal display panel with the aforementioned gate driving circuit mounted therein undergoes a high temperature/voltage reliability test, the second pull-down unit 50 and the third pull-down unit 60 in the gate driving unit tend to operate abnormally, which leads to erroneous image display.

### SUMMARY OF THE INVENTION

To the problem above, the present disclosure provides a gate driving circuit with prolonged service life and improved reliability, and an array substrate and a display panel thereof.

The gate driving circuit provided in the present disclosure includes multi-level gate driving units, wherein each gate driving unit outputs a gate signal through a gate line coupled to the gate driving unit, and each gate driving unit includes:

a starting unit configured to transmit an enabling signal;

an energy storage unit, coupled to the starting unit and configured to receive the enabling signal, execute a charging procedure according to the enabling signal, and output a driving voltage;

a pull-up unit, coupled to the energy storage unit and the gate line, and configured to receive the driving voltage, and pull up the gate signal on the gate line according to the driving voltage and a clock pulse signal;

a first pull-down unit, coupled to the energy storage unit and the gate line, and configured to pull down the driving voltage and the gate signal to a first reference voltage according to a first control signal; and

a second pull-down unit, coupled to the energy storage unit and the gate line, and configured to intermittently generate a second control signal according to the driving voltage and the clock pulse signal as well as a second reference voltage, and according to the second control signal, to pull down the driving voltage to the second reference voltage and pull down the gate signal to the first reference voltage.

Preferably, the second reference voltage is lower than the first reference voltage, and the first reference voltage is lower than zero.

The second pull-down unit includes:

a control module, coupled to the energy storage unit, and configured to receive the driving voltage and output the second control signal according to the driving voltage and the second reference voltage as well as the clock pulse signal;

a discharging module, coupled to the control module and the energy storage unit, and configured to receive the second control signal and pull down the driving voltage to the second reference voltage according to the second control signal; and

a pull-down module, coupled to the control module and the gate line, and configured to receive the second control signal and pull down the gate signal to the first reference voltage according to the second control signal.

The control module of the second pull-down unit includes:

a capacitor, including a first electrode, configured to receive the clock pulse signal, and a second electrode, serving as the an output terminal of the control module and coupled to the discharging module and the pull-down module; and

a transistor, including a first terminal, coupled to the second electrode of the capacitor, a control terminal, coupled to the energy storage unit, and a second terminal, configured to receive the second reference voltage.

The discharging module of the second pull-down unit includes one or more transistors in series connection, and one end of the discharging module is coupled to the energy storage unit, and the other end thereof is configured to receive the second reference voltage, and all the control terminals of the transistors are coupled to the control module to receive the second control signal.

The pull-down module of the second pull-down unit includes:

a transistor, including a first terminal coupled to the gate line, a control terminal coupled to the control module and configured to receive the second control signal, and a second terminal, configured to receive the first reference voltage.

The first pull-down unit includes:

a discharging module including one or more transistors in series connection, wherein one end of the discharging module is coupled to the energy storage unit and the other end thereof is configured to receive the first reference voltage, and all the control terminals of the transistors are configured to receive the first control signal; and

a pull-down module including a transistor, wherein a first terminal is coupled to the gate line, a second terminal is coupled to the first reference voltage, and a control terminal is configured to receive the first control signal.

In addition, each gate driving unit may further include a third pull-down unit, which is coupled to the energy storage unit and the gate line, and configured to intermittently generate a third control signal according to the driving voltage and the second reference voltage as well as another clock pulse signal which is inverse to the clock pulse signal, and according to the third control signal, to pull down the driving voltage to the second reference voltage and pull down the gate signal to the first reference voltage.

In addition, the present disclosure further provides an array substrate with the aforementioned gate driving circuit arranged thereon.

The present disclosure further provides a display panel, which includes the aforementioned array substrate.

In the present disclosure, by improving the second pull-down unit of the gate driving unit in the gate driving circuit, the second control signal can be intermittently generated according to the driving voltage and the clock pulse signal as well as the second reference voltage, such that the driving voltage and the gate signal on the gate line are pulled down to the second reference voltage, thereby shortening operating time and effectively prolonging service life.

In addition, to prevent leakage current between the first reference voltage and the second reference voltage from causing burnout of a chip for reference voltage supply, the transistor between the first reference voltage and the second reference voltage, through which the leakage current possibly passes, is modified to be a plurality of transistors in series connection, such that the possibility of current leakage is reduced. Therefore, the gate driving circuit, and the array substrate and the display panel thereof provided in the present disclosure have longer service life and improved reliability.

Other features and advantages of the present disclosure will be illustrated in the following description, and become partially apparent from the description or may be understood through implementing the present disclosure. The objects and other advantages of the present disclosure may be realized and obtained through the structures specified in the description, claims and accompanying drawings.

### BRIEF DESCRIPTION OF THE DRAWINGS

The drawings are provided for further understanding of the present disclosure, and constitute a part of the description to interpret the present disclosure together with the embodiments of the present disclosure, rather than limit to the present disclosure, wherein:

FIG. 1 is a diagram of constitution of a gate driving unit in a gate driving circuit in the prior art;

FIG. 2 is a schematic diagram of the circuit structure of the Nth gate driving unit in a gate driving circuit in the prior art;

FIG. 3 is a diagram of a gate signal output by the gate driving unit shown in FIG. 2 during an action period and an inaction period;

FIG. 4 is an operating time sequence diagram of the gate driving unit circuit shown in FIG. 2;

FIG. 5 is a schematic diagram of the circuit structure of a gate driving unit according to one embodiment of the present disclosure; and

FIG. 6 is a schematic diagram of the circuit structure of a leakage-current preventable gate driving unit according to one embodiment of the present disclosure.

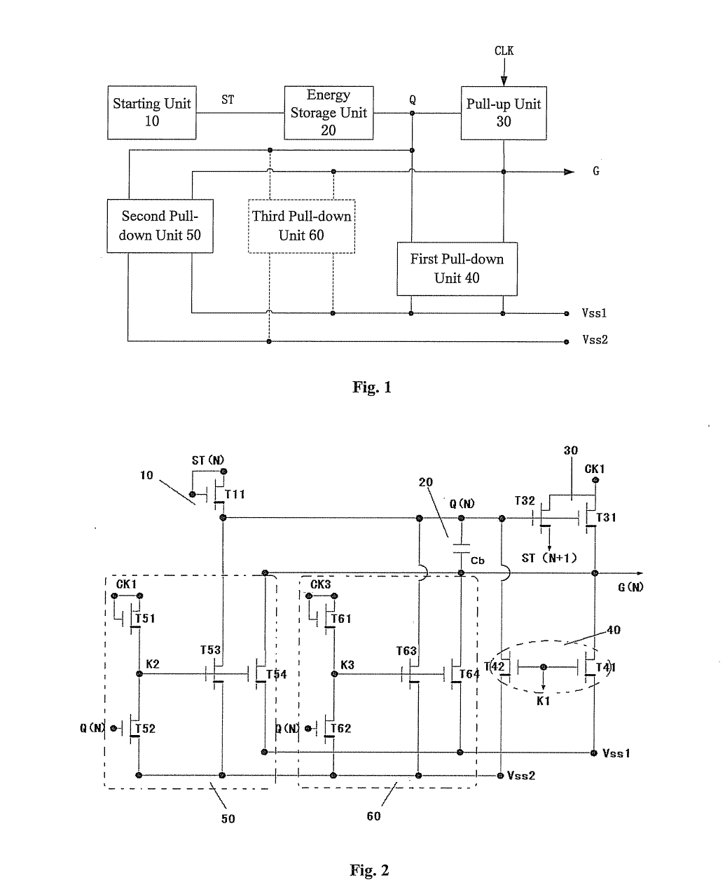

### DETAILED DESCRIPTION OF THE EMBODIMENTS

To illustrate the objectives, technical solutions and technical effects of the present disclosure, the reasons for the aforementioned faults and improvements made accordingly in the present disclosure will be analyzed below in details by taking a gate driving unit in the gate driving circuit shown in FIG. 2 as an example. It should be particularly noted that, although the present disclosure is illustrated on the basis of embodiments, the present disclosure is not limited thereto. The circuit structures in different types of display panels may differ from one another, thus any modifications and variations may be made to implementation forms and details by anyone skilled in the art related to the disclosure without departing from the spirit and scope disclosed in the present disclosure.

Shown in FIG. 2, it is a schematic diagram of the circuit structure of the Nth gate driving unit in an existing gate driving circuit. As described in the background of the invention, the gate driving unit may be divided into a starting unit 10, an energy storage unit 20, a pull-up unit 30, a first pull-down unit 40, a second pull-down unit 50, and a third pull-down unit 60.

The starting unit 10 includes a transistor T11, wherein a control terminal of the transistor T11 is in short coupling with a first terminal thereof to receive an enabling signal ST(N), and a second terminal thereof is coupled to the energy storage unit 20. When the high-level enabling signal ST(N) arrives, the transistor T11 is turned on and transmits the enabling signal ST(N) to the energy storage unit 20. wherein the enabling signal ST(N) may be a continued transmission signal from the previous gate driving unit, and certainly, may not be limited thereto.

The energy storage unit 20 includes a storage capacitor Cb, wherein a first electrode of the storage capacitor Cb is coupled to the second terminal of the transistor T11 to receive the enabling signal ST(N), and a second electrode of the storage capacitor Cb is coupled to a gate line. The storage capacitor Cb executes a charging procedure according to the enabling signal ST(N), and then the first electrode thereof outputs a high-level driving voltage Q(N) to the pull-up unit 30 after charging is completed.

The pull-up unit 30 includes transistors T31 and T32, wherein control terminals of the transistors T31 and T32 are both coupled to the first electrode of the storage capacitor Cb to receive the driving voltage Q(N), first terminals of the transistors T31 and T32 are both configured to receive a clock pulse signal CK1, and second terminals of the transistors T31 and T32 are respectively coupled to the gate line and an output line. Under the action of the driving voltage Q(N) and the clock pulse signal CK1, the transistors T31 and T32 respectively pull up a gate signal G(N) on the gate line and a continued transmission signal ST (N+1) on the output line to a high-level voltage. In this embodiment, the continued transmission signal ST (N+1) may be used as the enabling signal for the next gate driving unit and certainly, may not be limited thereto.

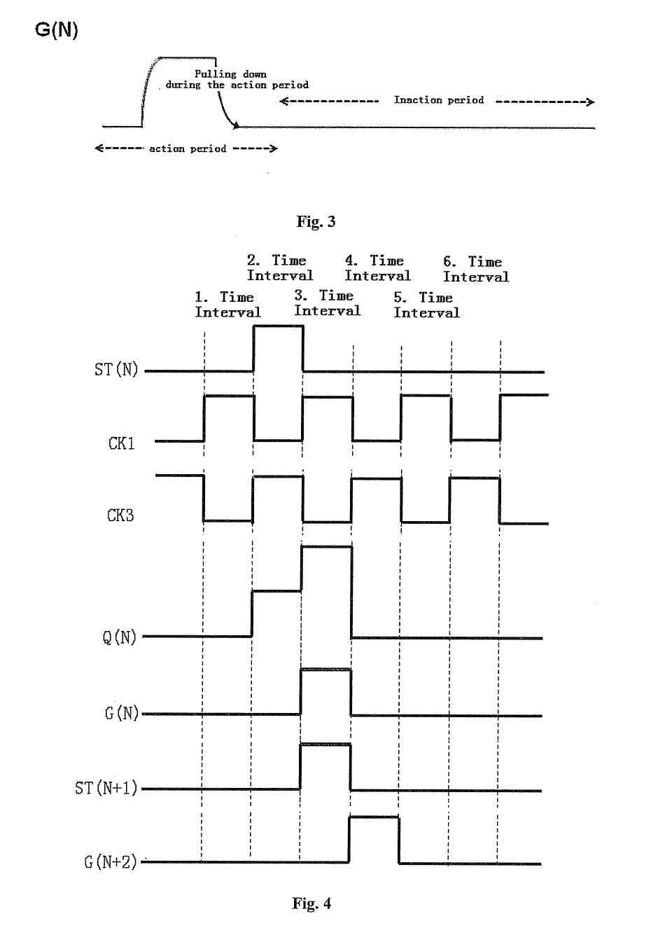

As shown in FIG. 3, the operating state of one gate driving unit may be typically divided into an action period and an inaction period based on the high and low level state of the gate signal G(N) output thereby: during the action period, the gate driving unit outputs the high-level gate signal G(N) to turn on the corresponding switch transistors in a display area; and during the inaction period, the gate driving unit outputs the low-level gate signal G(N) to turn off the corresponding switch transistors in the display area.

When the gate driving unit operates during the action period, the first pull-down unit 40 pulls down the driving voltage Q(N) and the gate signal G(N) to the first reference voltage Vss1 according to a first control signal K1, such that the gate driving unit is switched from the action period to the inaction period. Specifically, the first pull-down unit 40 includes a pull-down module 41 and a discharging module 42, wherein:

The pull-down module 41 includes a transistor T41, wherein a first terminal of the transistor T41 is coupled to the gate line, a second terminal thereof is configured to receive the first reference voltage Vss1, and a control terminal thereof is configured to receive the first control signal K1. Under the action of the first control signal K1, the first terminal of the transistor T41 is conducted with the second terminal, such that the gate signal G(N) is pulled down to the first reference voltage Vss1.

The discharge module 42 includes a transistor T42, wherein a first terminal of the transistor T42 is coupled to the first electrode of the storage capacitor Cb, a second terminal thereof is configured to receive the first reference voltage Vss1, and a control terminal thereof is configured to receive the first control signal K1. Under the action of the first control signal K1, the first terminal of the transistor T42 is conducted with the second terminal, such that the driving voltage Q(N) is pulled down to the first reference voltage Vss1. In this embodiment, the first control signal K1 may be a gate signal G(N+2) from the next second gate driving unit, and certainly, may not be limited thereto.

When the gate driving unit operates during the inaction period, charges are continuously accumulated at respective nodes of the circuit of the gate driving unit, and deviation of the voltage or current signals, such as the driving voltage Q(N) and the gate signal G(N), occurs when those charges are accumulated to a severe degree, which leads to abnormal outputs of the gate driving unit. To prevent this phenomenon from affecting the operating reliability of the circuit, the second pull-down unit 50 and the third pull-down unit 60 are used in this embodiment to pull down the driving voltage Q(N) and the gate signal G(N) in an alternate manner. Specifically, the second pull-down unit 50 includes a control module 51, a discharging module 52 and a pull-down module 53, wherein:

The control module 51 includes transistors T51 and T52, wherein a control terminal of the transistor T51 is in short coupling with a first terminal thereof to receive the clock pulse signal CK1, a second terminal of the transistor 51 serves as an output end of the control module 51 and is coupled to the discharge module 52, the pull-down module 53 and a first terminal of the transistor T52. A second terminal of the transistor T52 is configured to receive a second reference voltage Vss2, and a control terminal of the transistor T52 is coupled to the first electrode of the storage capacitor Cb to receive the driving voltage Q(N). When the driving voltage Q(N) is higher than the sum of the threshold voltage of the transistor T52 and the second reference voltage Vss2, the transistor T52 is turned on such that a second control signal K2 output by the control module 51 is present as the second reference voltage Vss2; and when the driving voltage Q(N) is equal to or lower than the sum of the threshold voltage of the transistor T52 and the second reference voltage Vss2, the transistor T52 is turned off such that the second control signal K2 output by the control module 51 is present as the clock pulse signal CK1 transmitted through the transistor T51.

The discharge module 52 includes a transistor T53, wherein a first terminal of the transistor T53 is coupled to the first electrode of the storage capacitor Cb, a second terminal thereof receives the second reference voltage Vss2, and a control terminal thereof is coupled to the second terminal of the transistor T51 to receive the second control signal K2, such that the driving voltage Q(N) is pulled down to the second reference voltage Vss2 according to the second control signal K2.

The pull-down module 53 includes a transistor T54, wherein a first terminal of the transistor T54 is coupled to the gate line, a second terminal of the transistor T54 is configured to receive the first reference voltage Vss1, and a control terminal thereof is coupled to the second terminal of the transistor T51 to receive the second control signal K2, such that the gate signal G(N) is pulled down to the first reference voltage Vss1 according to the second control signal K2.

The third pull-down unit 60 has the same constitution and function with the second pull-down unit 50. However, the difference of the third pull-down unit 60 from the second pull-down unit 50 lies in that, a control module 61 in the third pull-down unit 60 receives a clock pulse signal CK3 having inverse phase to the clock pulse signal CK1, and thereby generates a third control signal K3, such that a discharge module 62 is controlled to pull down the driving voltage Q(N) to the second reference voltage Vss2, and a pull-down module 63 is controlled to pull down the gate signal G(N) to the first reference voltage Vss1. The specific details are not described further herein.

In the aforementioned circuit, both the first reference voltage Vss1 and the second reference voltage Vss2 may be lower than zero, and preferably, the first reference voltage Vss1 may be higher than the second reference voltage Vss2 in order to prevent the phenomenon of current leakage in the pull-up unit T31. However, the present disclosure is not limited thereto.

The operation principle of the aforementioned gate driving unit will be discussed below in conjunction with FIG. 4.

During a first time interval, the enabling signal ST(N) is of low level, and thus the transistor T11 is turned off and the driving voltage Q(N) is low. Under the action of the driving voltage Q(N), the transistors T31 and T32 are turned off, and thus the gate signal G(N) and the continued transmission signal ST(N+1) are of low level. Meanwhile, under the action of the driving voltage Q(N), the transistor T52 is turned off, thereby the second control signal K2 is present as the clock pulse signal CK1. Because the clock pulse signal CK1 at this moment is of high level, the transistors T53 and T54 are thus turned on, such that the driving voltage Q(N) and the gate voltage G(N) are pulled down to the second reference voltage Vss2 and the first reference voltage Vss1 respectively. Under the action of the driving voltage Q(N), the transistor T62 is turned off, thereby the third control signal K3 is present as the clock pulse signal CK3, and because the clock pulse signal CK3 at this moment is of low level, the transistors T63 and T64 are thus turned off. At the same time, the first control signal G(N+2) is of low level, and thus the transistors T41 and T42 are turned off.

During a second time interval, the enabling signal ST(N) is switched to high level, and thus the transistor T11 is turned on, and the storage capacitor Cb executes the charging procedure and outputs the high-level driving voltage Q(N) at the first electrode of the storage capacitor Cb. Under the action of the driving voltage Q(N), the transistors T31 and T32 are turned on. Because the clock pulse signal CK1 at this moment is of low level, the gate signal G(N) and the continued transmission signal ST(N+1) are of low level. Meanwhile, under the action of the driving voltage Q(N), the transistor T52 is turned on, thereby the second control signal K2 is present as the second reference voltage Vss2, and the transistors T53 and T54 are turned off. Under the action of the driving voltage Q(N), the transistor T62 is turned on, thereby the third control signal K3 is present as the second reference voltage Vss2, and the transistors T63 and T64 are turned off. At the same time, the first control signal G(N+2) is of low level, and thus the transistors T41 and T42 are turned off.

During a third time interval, the enabling signal ST(N) is switched to low level, and thus the transistor T11 is turned off, but the high-level driving voltage Q(N) is still maintained at the first electrode of the storage capacitor Cb. Under the action of the driving voltage Q(N), the transistors T31 and T32 are turned on. Because the clock pulse signal CK1 at this moment is already switched from low level to high level, such that the gate signal G(N) and the continued transmission signal ST(N+1) are pulled up to a certain high level. Simultaneously, the driving voltage Q(N) is further pulled up to a higher level based upon rise of the gate signal G(N) and the continued transmission signal ST(N+1). Under the action of the driving voltage Q(N), the transistor T52 is turned on, thereby the second control signal K2 is present as the second reference voltage Vss2, and the transistors T53 and T54 are thus turned off. Meanwhile, under the action of the driving voltage Q(N), the transistor T62 is turned on, thereby the third control signal K3 is present as the second reference voltage Vss2, and the transistors T63 and T64 are turned off. At the same time, the first control signal G(N+2) is of low level, and the transistors T41 and T42 are thus turned off.

During a fourth time interval, the enabling signal ST(N) is of low level, and thus the transistor T11 is turned off. The first control signal G(N+2) is switched to high level, and the transistors T41 and T42 are turned on such that the driving voltage Q(N) and the gate voltage G(N) are pulled down to the first reference voltage Vss1. Under the action of the driving voltage Q(N), the transistors T31 and T32 are turned off. Meanwhile, under the action of the driving voltage Q(N), the transistor T52 is turned off, and the second control signal K2 is present as the clock pulse signal CK1. Because the clock pulse signal CK1 at this moment is of low level, the transistors T53 and T54 are turned off. Under the action of the driving voltage Q(N), the transistor T62 is turned off, and the third control signal K3 is present as the clock pulse signal CK3. Because the clock pulse signal CK3 at this moment is of high level, the transistors T63 and T64 are thereby turned on, such that the driving voltage Q(N) and the gate voltage G(N) are pulled down to the second reference voltage Vss2 and the first reference voltage Vss1 respectively.

During a fifth time interval, the enabling signal ST(N) is of low level, and thus the transistor T11 is turned off. Since the driving voltage Q(N) and the gate voltage G(N) are already pulled down to the second reference voltage Vss2 and the first reference voltage Vss1 respectively. Under the action of the driving voltage Q(N), the transistors T31 and T32 are thus turned off. Meanwhile, under the action of the driving voltage Q(N), the transistor T52 is turned off, and the second control signal K2 is present as the clock pulse signal CK1. Because the clock pulse signal CK1 at this moment is of high level, the transistors T53 and T54 are turned on, such that the driving voltage Q(N) and the gate voltage G(N) are pulled down to the second reference voltage Vss2 and the first reference voltage Vss1 respectively. Under the action of the driving voltage Q(N), the transistor T62 is turned off, and the third control signal K3 is present as the clock pulse signal CK3. Because the clock pulse signal CK3 at this moment is of low level, the transistors T63 and T64 are turned off. At the same time, the first control signal G(N+2) is switched to low level, and the transistors T41 and T42 are thus turned off. Therefore, it is clear from above that the operating status of the gate driving unit during the fifth time interval is the same with that of the first time interval.

During a sixth time interval, the enabling signal ST(N) is of low level, and thus the transistor T11 is turned off. Since the driving voltage Q(N) and the gate voltage G(N) are already pulled down to the second reference voltage Vss2 and the first reference voltage Vss1 respectively. Under the action of the driving voltage Q(N), the transistors T31 and T32 are thereby turned off. Meanwhile, under the action of the driving voltage Q(N), the transistor T52 is turned off, and the second control signal K2 is present as the clock pulse signal CK1. Because the clock pulse signal CK1 at this moment is of low level, the transistors T53 and T54 are thus turned off. Under the action of the driving voltage Q(N), the transistor T62 is turned off, and the third control signal K3 is present as the clock pulse signal CK3. Because the clock pulse signal CK3 at this moment is of high level, the transistors T63 and T64 are turned on, such that the driving voltage Q(N) and the gate voltage G(N) are pulled down to the second reference voltage Vss2 and the first reference voltage Vss1 respectively. That is, the driving voltage Q(N) is maintained at the second reference voltage Vss2 and the gate voltage G(N) is maintained at the first reference voltage Vss1. At the same time, the first control signal G(N+2) is of low level, and thereby the transistors T41 and T42 are turned off. Therefore, it is clear from above that, as long as no new enabling signal ST(N) is input thereafter, the gate driving unit may repeat the fifth time interval and the sixth time interval, such that the driving voltage Q(N) and the gate voltage G(N) are maintained in a low level state.

The second pull-down unit 50 and the third pull-down unit 60 operate in an alternate manner to pull down the driving voltage Q(N) and the gate voltage G(N). However, it is found through long-term researches and tests by those researchers of the present disclosure that, the condition of alternate operation between the second pull-down unit 50 and the third pull-down unit 60 is not quite satisfactory in practice. Specifically, after a liquid crystal display panel mounted with the aforementioned gate driving circuit undergoes a high temperature-voltage reliability test, the second pull-down unit 50 and the third pull-down unit 60 in the gate driving unit may tend to operate abnormally. This is because that the transistor T51 in the second pull-down unit 50 is equivalent to a diode. When the clock pulse signal CK1 is of high level, the transistor T51 is turned on, and the charges are accumulated at the second terminal of the transistor T51. However, when the clock pulse signal CK1 is of low level, the transistor T51 is turned off, and those charges accumulated at the second terminal of the transistor T51 cannot be dispersed in time. As a result of this, the transistors T53 and T54 fail to stop but keep an operating state for a long-term, which leads to worse reliability and shortened service life. Likewise, a same situation is happened to the transistor T61 in the third pull-down unit 60.

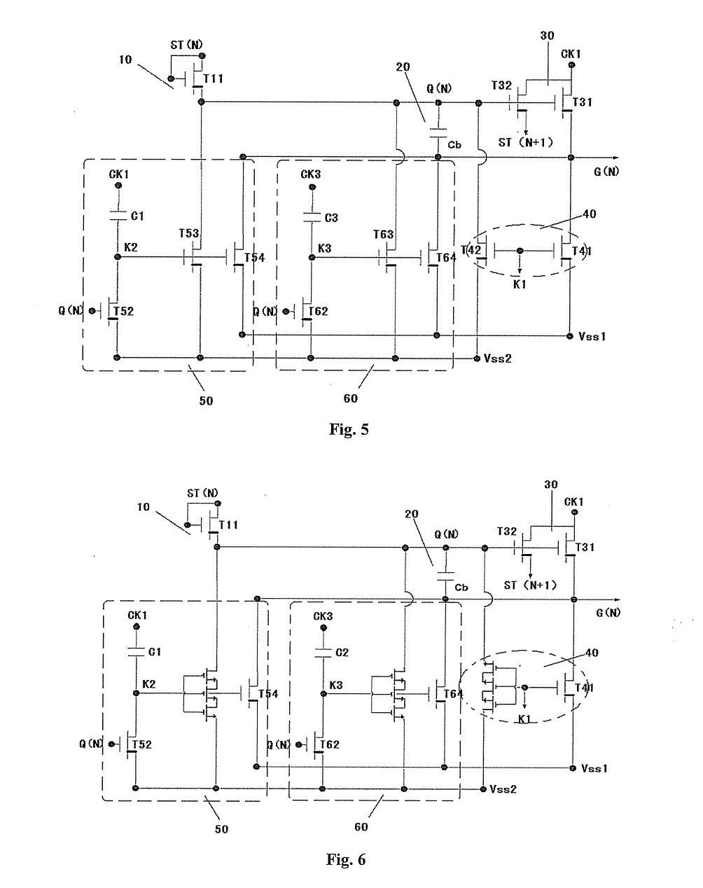

To improve the condition above, the present disclosure provides a new technical solution below. As shown in FIG. 5, the transistors T51 and T61 in the second pull-down unit 50 and the third pull-down unit 60 are modified to be capacitors C1 and C3, respectively. The first electrode of the capacitor C1 receives the clock pulse signal CK1 and the first electrode of the capacitor C3 receives the clock pulse signal CK3. The second electrode of C1 serves as the output terminal for the second control signal K2 and is coupled to the transistor T52, while the second electrode of C3 serves as the output terminal for the third control signal K3 and is coupled to the transistor T62. The coupling effect of the capacitors C1 and C3 enables the second control signal K2 and the third control signal K3 to change respectively along with the changes of the clock pulse signals CK1 and CK3. Thus, there is a possibility of completely turning off the transistors T53 and T54 as well as the transistors T63 and T64 in accordance with the operating principle introduced above, such that the effect of alternate operation may be realized. In addition, since currents passing by the capacitors C1 and C2 are extremely low, this circuit may have lower dynamic power consumption than the original circuit structure.

Further, since the second reference voltage Vss2 is lower than the first reference voltage Vss1 in the original gate driving unit, there may be leakage current flowing from the first reference voltage Vss1 to the second reference voltage Vss2 via the transistors T42, T53 and T63, such that a power supply chip for providing the first reference voltage Vss1 may be under an operating state of outputting negative voltages and positive currents for a long time and finally burnt out, which leads to abnormality of image display. In view of this, an improved approach used in the present disclosure is that a transistor, through which the leakage current possibly passes, between the first reference voltage Vss1 and the second reference voltage Vss2 may be modified to be a plurality of transistors in series connection. In the embodiment of the present disclosure, as shown in FIG. 6, the transistors T42, T53 and T63 are all replaced by three transistors in series connection, in order to prevent the leakage current from flowing to the second reference voltage Vss2 from the first reference voltage Vss1. As it should be, the present disclosure may not be limited thereto.

In another aspect, the present disclosure further provides an array substrate with the aforementioned gate driving circuit arranged thereon.

In another aspect, the present disclosure further provides a display panel including the aforementioned array substrate.

Although the embodiments of the present disclosure have been disclosed as above, the contents described herein are merely the embodiments for a better understanding of the present disclosure, rather than limit thereto. Any modifications and variations could be made to the implementation forms and details by any one skilled in the art related to the present disclosure without departing from the spirit and scope disclosed in the present disclosure, but the patent protection scope of the present disclosure is still subjected to the scope defined by the claims.

1. A gate driving circuit, including multi-level gate driving units, wherein a gate driving unit of each level outputs a gate signal through a gate line coupled thereto, the gate driving unit of each level comprising:
a starting unit configured to transmit an enabling signal;
an energy storage unit coupled to the starting unit and configured to receive the enabling signal, execute a charging procedure based on the enabling signal, and output a driving voltage;
a pull-up unit coupled to the energy storage unit and the gate line, and configured to receive the driving voltage, and pull up the gate signal on the gate line based on the driving voltage and a clock pulse signal;
a first pull-down unit coupled to the energy storage unit and the gate line, and configured to pull the driving voltage and the gate signal down to a first reference voltage based on a first control signal; and
a second pull-down unit coupled to the energy storage unit and the gate line, and configured to intermittently generate a second control signal based on the driving voltage, the clock pulse signal as well as a second reference voltage, and based on the second control signal, to pull down the driving voltage to the second reference voltage and pull down the gate signal to the first reference voltage.

2. The gate driving circuit of claim 1, wherein the second reference voltage is lower than the first reference voltage, and the first reference voltage is lower than zero.

3. The gate driving circuit of claim 1, wherein the second pull-down unit including:
a control module coupled to the energy storage unit, and configured to receive the driving voltage, and output the second control signal based on the driving voltage, the second reference voltage and the clock pulse signal;
a discharging module coupled to the control module and the energy storage unit, and configured to receive the second control signal, and pull the driving voltage down to the second reference voltage based on the second control signal; and
a pull-down module coupled to the control module and the gate line, and configured to receive the second control signal, and pull the gate signal down to the first reference voltage based on the second control signal.

4. The gate driving circuit of claim 2, wherein the second pull-down unit including:
a control module coupled to the energy storage unit, and configured to receive the driving voltage, and output the second control signal based on the driving voltage, the second reference voltage and the clock pulse signal;
a discharging module coupled to the control module and the energy storage unit, and configured to receive the second control signal, and pull the driving voltage down to the second reference voltage based on the second control signal; and
a pull-down module coupled to the control module and the gate line, and configured to receive the second control signal, and pull the gate signal down to the first reference voltage based on the second control signal.

5. The gate driving circuit of claim 3, wherein the control module of the second pull-down unit includes:
a capacitor, including:
a first electrode configured to receive the clock pulse signal, and
a second electrode serving as an output terminal of the control module and coupled to the discharging module and the pull-down module;
a transistor, including:
a first terminal coupled to the second electrode of the capacitor,
a control terminal coupled to the energy storage unit, and
a second terminal configured to receive the second reference voltage.

6. The gate driving circuit of claim 4, wherein the control module of the second pull-down unit includes:
a capacitor, including:
a first electrode configured to receive the clock pulse signal, and
a second electrode serving as an output terminal of the control module and coupled to the discharging module and the pull-down module;
a transistor, including:
a first terminal coupled to the second electrode of the capacitor,
a control terminal coupled to the energy storage unit, and
a second terminal configured to receive the second reference voltage.

7. The gate driving circuit of claim 3, wherein the discharging module of the second pull-down unit includes one or more transistors in series connection, wherein one end of the discharging module is coupled to the energy storage unit, and the other end thereof is configured to receive the second reference voltage, and all the control terminals of the transistors are coupled to the control module to receive the second control signal.

8. The gate driving circuit of claim 4, wherein the discharging module of the second pull-down unit includes one or more transistors in series connection, wherein one end of the discharging module is coupled to the energy storage unit, and the other end thereof is configured to receive the second reference voltage, and all the control terminals of the transistors are coupled to the control module to receive the second control signal.

9. The gate driving circuit of claim 3, wherein the pull-down module of the second pull-down unit includes:
a transistor, including a first terminal coupled to the gate line, a control terminal coupled to the control module and configured to receive the second control signal, and a second terminal configured to receive the first reference voltage.

10. The gate driving circuit of claim 4, wherein the pull-down module of the second pull-down unit includes:
a transistor, including a first terminal coupled to the gate line, a control terminal coupled to the control module and configured to receive the second control signal, and a second terminal configured to receive the first reference voltage.

11. The gate driving circuit of claim 1, wherein the first pull-down unit including:
a discharging module including one or more transistors in series connection, wherein one end of the discharging module is coupled to the energy storage unit and the other end thereof is configured to receive the first reference voltage, and all the control terminals of the transistors are configured to receive the first control signal; and
a pull-down module including a transistor, wherein a first terminal is coupled to the gate line, a second terminal is coupled to the first reference voltage, and a control terminal is configured to receive the first control signal.

12. The gate driving circuit of claim 2, wherein the first pull-down unit including:
a discharging module including one or more transistors in series connection, wherein one end of the discharging module is coupled to the energy storage unit and the other end thereof is configured to receive the first reference voltage, and all the control terminals of the transistors are configured to receive the first control signal; and
a pull-down module including a transistor, wherein a first terminal is coupled to the gate line, a second terminal is coupled to the first reference voltage, and a control terminal is configured to receive the first control signal.

13. The gate driving circuit of claim 1, wherein the gate driving unit of each level comprising:
the third pull-down unit coupled to the energy storage unit and the gate line, and configured to intermittently generate a third control signal based on the driving voltage, the second reference voltage and another clock pulse signal which is inverse to the clock pulse signal, and based on the third control signal, to pull the driving voltage down to the second reference voltage and pull the gate signal down to the first reference voltage.

14. The gate driving circuit of claim 2, wherein the gate driving unit of each level further comprising:
the third pull-down unit coupled to the energy storage unit and the gate line, and configured to intermittently generate a third control signal based on the driving voltage, the second reference voltage and another clock pulse signal which is inverse to the clock pulse signal, and based on the third control signal, to pull the driving voltage down to the second reference voltage and pull the gate signal down to the first reference voltage.

15. An array substrate, including a gate driving circuit with multi-level gate driving units, wherein a gate driving unit of each level outputs a gate signal through a gate line coupled thereto, the gate driving unit of each level comprising:
a starting unit configured to transmit an enabling signal;
an energy storage unit coupled to the starting unit and configured to receive the enabling signal, execute a charging procedure based on the enabling signal, and output a driving voltage;
a pull-up unit coupled to the energy storage unit and the gate line, and configured to receive the driving voltage, and pull up the gate signal on the gate line based on the driving voltage and a clock pulse signal;
a first pull-down unit coupled to the energy storage unit and the gate line, and configured to pull the driving voltage and the gate signal down to a first reference voltage based on a first control signal; and
a second pull-down unit coupled to the energy storage unit and the gate line, and configured to intermittently generate a second control signal based on the driving voltage, the clock pulse signal as well as a second reference voltage, and based on the second control signal, to pull down the driving voltage to the second reference voltage and pull down the gate signal to the first reference voltage.

16. The array substrate of claim 15, wherein the second reference voltage is lower than the first reference voltage, and the first reference voltage is lower than zero.

17. The array substrate of claim 15, wherein the gate driving unit of each level further comprising:
the third pull-down unit coupled to the energy storage unit and the gate line, and configured to intermittently generate a third control signal based on the driving voltage, the second reference voltage and another clock pulse signal which is inverse to the clock pulse signal, and based on the third control signal, to pull the driving voltage down to the second reference voltage and pull the gate signal down to the first reference voltage.

18. A display panel including an array substrate, the array substrate including a gate driving circuit with multi-level gate driving units, wherein a gate driving unit of each level outputs a gate signal through a gate line coupled thereto, the gate driving unit of each level comprising:
a starting unit configured to transmit an enabling signal;
an energy storage unit coupled to the starting unit and configured to receive the enabling signal, execute a charging procedure based on the enabling signal, and output a driving voltage;
a pull-up unit coupled to the energy storage unit and the gate line, and configured to receive the driving voltage, and pull up the gate signal on the gate line based on the driving voltage and a clock pulse signal;
a first pull-down unit coupled to the energy storage unit and the gate line, and configured to pull the driving voltage and the gate signal down to a first reference voltage based on a first control signal; and
a second pull-down unit coupled to the energy storage unit and the gate line, and configured to intermittently generate a second control signal based on the driving voltage, the clock pulse signal as well as a second reference voltage, and based on the second control signal, to pull down the driving voltage to the second reference voltage and pull down the gate signal to the first reference voltage.

19. The display panel of claim 18, wherein the second reference voltage is lower than the first reference voltage, and the first reference voltage is lower than zero.

20. The display panel of claim 18, wherein the gate driving unit of each level further comprising:
the third pull-down unit coupled to the energy storage unit and the gate line, and configured to intermittently generate a third control signal based on the driving voltage, the second reference voltage and another clock pulse signal which is inverse to the clock pulse signal, and based on the third control signal, to pull the driving voltage down to the second reference voltage and pull the gate signal down to the first reference voltage.
